(19) United States
(12) Patent Application Publication
(10) Pub. No.: US 2026/0011532 A1
(43) Pub. Date: Jan. 8, 2026

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Tadashi TAKASAKI, Toyama (JP); Tatsushi UEDA, Toyama (JP)

(73) Assignee: Kokusai Electric Corporation, Tokyo (JP)

(21) Appl. No.: 19/330,229

(22) Filed: Sep. 16, 2025

Related U.S. Application Data
(63) Continuation of application No. PCT/JP2023/011380, filed on Mar. 23, 2023.

(51) Int. Cl. H01J 37/32

(52) U.S. Cl. CPC H01J 37/32348; H01J 37/32715; H01J 37/32834; H01J 2237/334

(57) ABSTRACT

There is provided a technique that includes: a process chamber in which a substrate is processed; a dielectric structure provided in the process chamber; an electromagnetic wave supplier configured to supply an electromagnetic wave to the dielectric structure; a heating medium supplier capable of supplying a heating medium to the dielectric structure; and a controller configured to be capable of controlling a supply of the heating medium to the dielectric structure such that the heating medium is supplied to the dielectric structure when a temperature of the dielectric structure is equal to or lower than a predetermined temperature before processing the substrate.

### CROSS-REFERENCE TO RELATED PATENT APPLICATION

This application is a bypass continuation application of PCT International Application No. PCT/JP2023/011380, filed on Mar. 23, 2023, in the WIPO, the entire contents of which are hereby incorporated by reference.

### BACKGROUND

### 1. Field

The present disclosure relates to a substrate processing apparatus, a substrate processing method, a method of manufacturing a semiconductor device and a non-transitory computer-readable recording medium.

### 2. Related Art

According to some related arts, as an apparatus configured to manufacture a semiconductor device, an apparatus configured to process a substrate using a plasma generated by an electromagnetic wave may be used. In addition, according to some related arts, when processing a plurality of substrates, it is preferable to perform a processing uniformly with respect to each of the substrates.

When processing the substrates, one or more among the substrates may be replaced. However, when replacing the substrates, for example, a temperature of a process chamber in which the substrates are processed may be lowered. Thereby, a processing environment may vary (or change) before and after a replacement related thereto. As a result, a variation in a film quality (that is, a variation in a quality of a film formed on each of the substrates by performing the processing) may occur between the substrates.

### SUMMARY

According to the present disclosure, there is provided a technique capable of processing a plurality of substrates such that a film quality is uniformized even when a processing environment between the plurality of substrates varies.

According to an embodiment of the present disclosure, there is provided a technique that includes: a process chamber in which a substrate is processed; a dielectric structure provided in the process chamber; an electromagnetic wave supplier configured to supply an electromagnetic wave to the dielectric structure; a heating medium supplier capable of supplying a heating medium to the dielectric structure; and a controller configured to be capable of controlling a supply of the heating medium to the dielectric structure such that the heating medium is supplied to the dielectric structure when a temperature of the dielectric structure is equal to or lower than a predetermined temperature before processing the substrate.

### BRIEF DESCRIPTION OF THE DRAWINGS

FIG. 1 is a diagram schematically illustrating an exemplary configuration of a substrate processing apparatus according to a first embodiment of the present disclosure.

FIG. 2A is a diagram schematically illustrating an exemplary configuration of a first gas supplier according to the first embodiment of the present disclosure.

FIG. 2B is a diagram schematically illustrating an exemplary configuration of a second gas supplier according to the first embodiment of the present disclosure.

FIG. 2C is a diagram schematically illustrating an exemplary configuration of a third gas supplier according to the first embodiment of the present disclosure.

FIG. 3 is a block diagram schematically illustrating a configuration of a controller and related components thereof according to the first embodiment of the present disclosure.

FIG. 4 is a diagram schematically illustrating a table stored in the controller according to the first embodiment of the present disclosure.

FIG. 5 is a diagram schematically illustrating another table stored in the controller according to the first embodiment of the present disclosure.

FIG. 6 is a flow chart schematically illustrating a substrate processing according to the first embodiment of the present disclosure.

FIG. 7 is a flow chart schematically illustrating a film forming step according to the first embodiment of the present disclosure.

FIG. 8 is a diagram schematically illustrating an exemplary configuration of a substrate processing apparatus according to a second embodiment of the present disclosure.

FIG. 9 is a diagram schematically illustrating a vertical cross-section of the substrate processing apparatus according to the second embodiment of the present disclosure.

FIG. 10 is a diagram schematically illustrating an exemplary configuration of a gas supplier according to the second embodiment of the present disclosure.

FIG. 11 is a diagram schematically illustrating an exemplary configuration of a substrate processing apparatus according to a third embodiment of the present disclosure.

### DETAILED DESCRIPTION

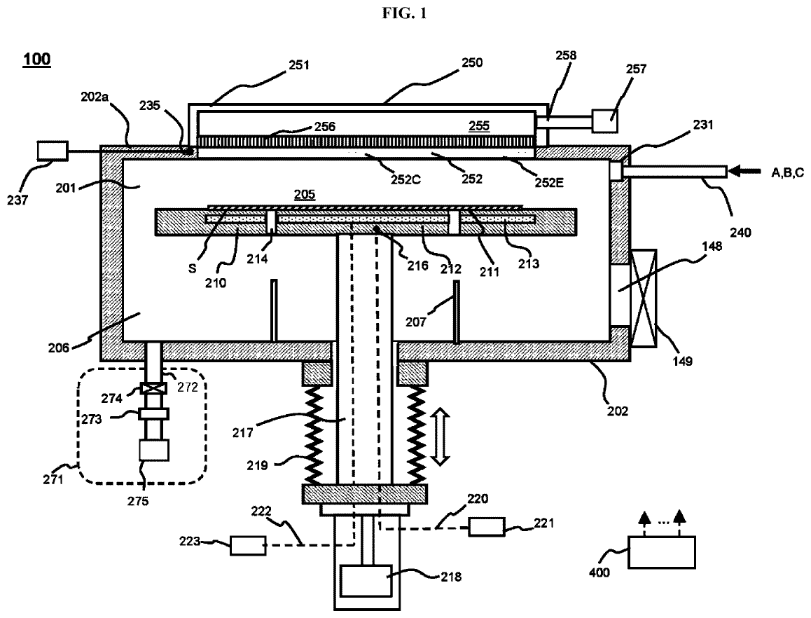

Hereinafter, embodiments of the technique of the present disclosure will be described in detail mainly with reference to FIGS. 1 to 11. The drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match.

### First Embodiment

Hereinafter, a first embodiment of the technique of the present disclosure will be described in detail mainly with reference to FIGS. 1 to 7. FIG. 1 is a diagram schematically illustrating a vertical cross-section of an exemplary configuration of a substrate processing apparatus 100 according to the first embodiment of the present disclosure.

As shown in FIG. 1, the substrate processing apparatus 100 includes a vessel 202. The vessel 202 is configured as a flat sealed vessel whose horizontal cross-section is of a circular shape. For example, the vessel 202 is made of a metal material such as aluminum (Al) and stainless steel (SUS). A process chamber 201 constituting a process space 205 (in which a substrate S such as a silicon wafer is processed) is provided in the vessel 202.

A substrate loading/unloading port 148 adjacent to a gate valve 149 is provided on a side surface of the vessel 202, and the substrate S is transferred (loaded) into or transferred (unloaded) out of the vessel 202 through the substrate loading/unloading port 148. A space adjacent to the substrate loading/unloading port 148 may also be referred to as a “transfer space 206”. A plurality of lift pins 207 are provided at a lower portion of the vessel 202. In addition, an exhaust pipe 272 described later is provided.

A substrate support 210 configured to support the substrate S is provided in the vessel 202. The substrate support 210 mainly includes: a substrate support table 212 provided with a support surface 211 on which the substrate S can be supported; and a heater 213 serving as a heating structure provided in the substrate support table 212. A plurality of through-holes 214 through which the lift pins 207 penetrate are provided at positions of the substrate support table 212 in a manner corresponding to the lift pins 207.

In addition, a temperature measurer (which is a temperature measuring structure) 216 capable of measuring a temperature of the heater 213 is provided in the substrate support table 212. The temperature measurer 216 serves as a first temperature measurer. The temperature measurer 216 is connected to a temperature meter 221 serving as a first temperature meter via a wiring 220. A wiring 222 through which an electric power is supplied (applied) is connected to the heater 213. The wiring 222 is further connected to a heater controller 223.

The temperature meter 221 and the heater controller 223 are electrically connected to a controller 400 described later. The controller 400 is configured to transmit control information to the heater controller 223 based on temperature information measured by the temperature meter 221. The heater controller 223 is configured to control the heater 213 by referring to the control information received from the controller 400.

The substrate support table 212 is supported by a shaft 217. The shaft 217 penetrates the lower portion (bottom) of the vessel 202, and is connected to an elevator (which is an elevating structure) 218 at an outside (outer portion) of the vessel 202. The elevator 218 is configured to elevate (or lower) and to rotate the shaft 217. A bellows 219 covers a periphery of a lower end of the shaft 217 to maintain an inside (inner portion) of the process space 205 airtight.

When the substrate S is transferred, the substrate support table 212 is lowered until the support surface 211 faces the substrate loading/unloading port 148, that is, until a transfer position of the substrate S is reached. When the substrate S is processed, the substrate support table 212 is elevated until the substrate S reaches a processing position (also referred to as a “substrate processing position”) in the process space 205 as shown FIG. 1.

Subsequently, an electromagnetic wave supplier (which is an electromagnetic wave supply structure) 250 will be described. The electromagnetic wave supplier 250 is provided above the process space 205.

A vessel 251 constituting the electromagnetic wave supplier 250 is provided on a ceiling 202a of the vessel 202. A dielectric plate (which is an example of a dielectric structure) 252 made of a dielectric material is provided between the vessel 251 and the substrate support table 212. The dielectric plate 252 is configured to close a hole provided in an upper wall of the ceiling 202a. A slot plate 256 is provided above the dielectric plate 252. The slot plate 256 is provided with a plurality of radiation holes. A main surface (primary surface) of the dielectric plate 252 is configured to be parallel to a main surface (front surface) of the substrate S supported by the substrate support 210. A temperature measurer 235 capable of measuring a temperature of the dielectric plate 252 is provided in the vicinity of the dielectric plate 252, for example, on the ceiling 202a. The temperature measurer 235 serves as a second temperature measurer. The temperature measurer 235 is connected to a temperature meter 237 serving as a second temperature meter.

A space 255 is provided between an upper surface of the slot plate 256 and an inner wall of the vessel 251. A waveguide 258 is connected to the vessel 251. A microwave supply source 257 is connected to the waveguide 258, and a microwave serving as an electromagnetic wave generated from the microwave supply source 257 is supplied to the space 255 through the waveguide 258. The vessel 251 and the waveguide 258 are collectively referred to as a “microwave supplier” which is a microwave supply structure. The microwave supplier may also include the microwave supply source 257.

The vessel 202 is provided with a gas supply pipe 240 through which a gas is supplied toward the dielectric plate 252 from below the dielectric plate 252. A gas supply hole 231 of a circular shape is provided at a front end (tip) of the gas supply pipe 240 along a side wall of the vessel 202. The gas after passed through the gas supply pipe 240 is supplied toward the dielectric plate 252 from below the dielectric plate 252 through the gas supply hole 231.

The gas supply hole 231 is configured to communicate with a first gas supplier (which is a first gas supply structure) 241, a second gas supplier (which is a second gas supply structure) 242 and a third gas supplier 243 (which is a third gas supply structure), which will be described later. Although a single gas supply hole 231 is provided for the gas suppliers as shown in FIG. 1, a plurality of gas supply holes including the gas supply hole 231 may be provided for the gas suppliers, respectively. A first gas supply pipe 241a, a second gas supply pipe 242a and a third gas supply pipe 243a, which will be described later, are connected to the gas supply pipe 240.

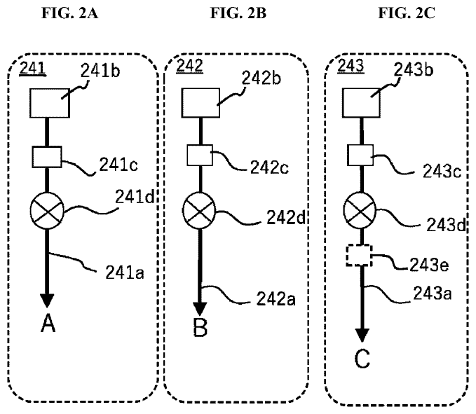

The first gas supplier 241 will be described with reference to FIG. 2A. A first gas supply source 241b, a mass flow controller (MFC) 241c serving as a flow rate controller (flow rate control structure) and a valve 241d serving as an opening/closing valve are sequentially provided at the first gas supply pipe 241a in this order from an upstream side toward a downstream side of the first gas supply pipe 241a in a gas flow direction.

The first gas supply source 241b is a source of a first gas (hereinafter, also referred to as a “first element-containing gas”) containing a first element. The first element-containing gas serves as a source gas, that is, one of process gases. In the present embodiment, for example, the first element is silicon (Si). That is, for example, the first element-containing gas is a silicon-containing gas. Specifically, as the silicon-containing gas, dichlorosilane (SiH₂Cl₂, also referred to as “DCS”) gas may be used. The first gas supplier 241 is constituted mainly by the first gas supply pipe 241a, the MFC 241c and the valve 241d. In addition, the first gas supplier 241 may also be referred to as a “silicon-containing gas supplier” which is a silicon-containing gas supply structure.

The second gas supplier 242 will be described with reference to FIG. 2B. A second gas supply source 242b, a mass flow controller (MFC) 242c and a valve 242d are sequentially provided at the second gas supply pipe 242a in this order from an upstream side toward a downstream side of the second gas supply pipe 242a in the gas flow direction.

The second gas supply source 242b is a source of a second gas (hereinafter, also referred to as a “second element-containing gas”) containing a second element. The second element-containing gas is one of the process gases. For example, the second element-containing gas may serve as a reactive gas or a modifying gas. Hereinafter, each of the process gases may also be referred to as a “process gas”.

In the present embodiment, the second element-containing gas contains the second element different from the first element. For example, the second element is one of oxygen (O), nitrogen (N) and carbon (C). In the technique of the present disclosure, for example, the second element-containing gas is a nitrogen-containing gas. Specifically, as the nitrogen-containing gas, ammonia (NH₃) gas may be used. The second gas supplier 242 is constituted mainly by the second gas supply pipe 242a, the MFC 242c and the valve 242d. The second gas supplier 242 may also be referred to as a “reactive gas supplier” which is a reactive gas supply structure.

The third gas supplier 243 will be described with reference to FIG. 2C. A third gas supply source 243b, a mass flow controller (MFC) 243c and a valve 243d serving as an opening/closing valve are sequentially provided at the third gas supply pipe 243a in this order from an upstream side toward a downstream side of the third gas supply pipe 243a in the gas flow direction.

The third gas supply source 243b is an inert gas supply source. For example, an inert gas is nitrogen (N₂) gas. The inert gas may also be referred to as a “third gas”. The third gas supply pipe 243a may be provided with a heating structure 243e capable of heating the gas passing through the third gas supply pipe 243a. The third gas supplier 243 is constituted mainly by the third gas supply pipe 243a, the MFC 243c and the valve 243d. Since a heating medium described later is supplied through the third gas supplier 243, the third gas supplier 243 may also be referred to as a “heating medium supplier” which is a heating medium supply structure.

In a substrate processing described later, the inert gas supplied from the third gas supply source (inert gas supply source) 243b acts as a purge gas for purging the gas remaining in the vessel 202. In a temperature adjusting step described later, the inert gas acts as the heating medium capable of heating the dielectric plate 252.

In the present specification, a combination of the first gas supplier 241, the second gas supplier 242 and the third gas supplier 243 may also be referred to as a “gas supplier” which is a gas supply structure, or the first gas supplier 241, the second gas supplier 242, and the third gas supplier 243 may also be collectively referred to as the “gas supplier”. In addition, since the heating medium may be supplied through the gas supplier, a combination of the first gas supplier 241, the second gas supplier 242 and the third gas supplier 243 may also be referred to as the “heating medium supplier”, or the first gas supplier 241, the second gas supplier 242, and the third gas supplier 243 may also be collectively referred to as the “heating medium supplier”.

The exhaust pipe 272 is provided to communicate with the process space 205. That is, the exhaust pipe 272 is connected to the vessel 202 so as to be in communication with the process space 205. An APC (Automatic Pressure Controller) 273 is provided at the exhaust pipe 272. The APC 273 serves as a pressure controller configured to control a pressure (inner pressure) of the process space 205 to a predetermined pressure. The APC 273 includes a valve structure (not shown) whose opening degree can be adjusted, and is configured to adjust a conductance of the exhaust pipe 272 in accordance with an instruction from the controller 400. In addition, a valve 274 is provided at the exhaust pipe 272 at an upstream side of the APC 273. The exhaust pipe 272, the valve 274 and the APC 273 may be collectively referred to as an “exhauster” 271 which is an exhaust structure. In addition, a DP (Dry Pump) 275 is provided at a downstream side of the exhaust pipe 272. The DP 275 is configured to exhaust an atmosphere (inner atmosphere) of the process space 205 through the exhaust pipe 272. The exhauster 271 may further include the DP 275.

The substrate processing apparatus 100 is provided with the controller 400 configured to control operations of components constituting the substrate processing apparatus 100.

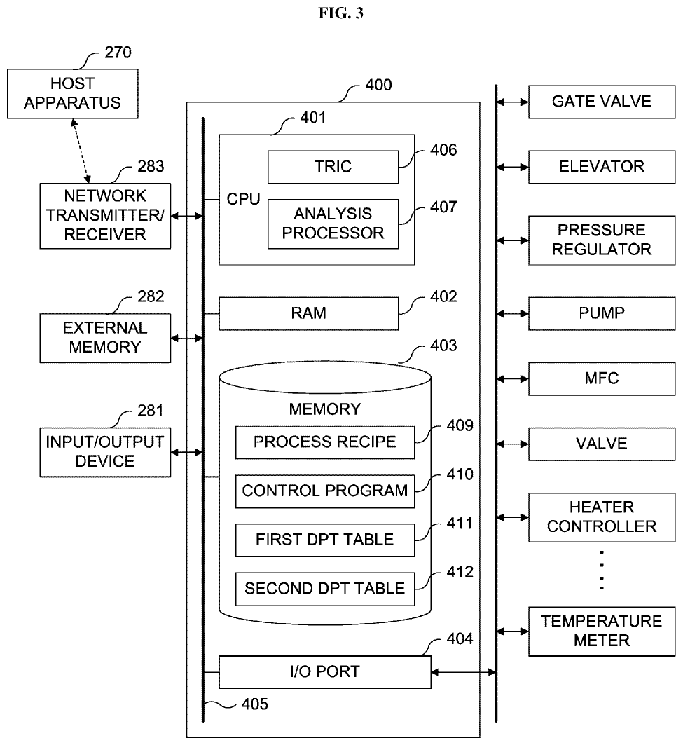

FIG. 3 is a block diagram schematically illustrating a configuration of the controller 400 and related components thereof. The controller 400 serving as a control structure may be embodied by a computer including a CPU (Central Processing Unit) 401, a RAM (Random Access Memory) 402, a memory 403 serving as a storage and an I/O port (input/output port) 404. The RAM 402, the memory 403 and the I/O port 404 are configured to exchange data with the CPU 401 via an internal bus 405. The transmission/reception of the data in the substrate processing apparatus 100 may be performed in accordance with an instruction from a transmission/reception instruction controller (“TRIC” shown in FIG. 3) 406 which is one of functions of the CPU 401.

The CPU 401 further includes an analysis processor 407. The analysis processor 407 is configured to analyze a relationship between a table stored in the memory 403 and the temperature information measured by the temperature meters 221 and 237.

A network transmitter/receiver 283 connected to a host apparatus 270 via a network is provided at the controller 400. For example, the network transmitter/receiver 283 is capable of receiving data such as information regarding a processing history and a processing schedule for the substrate S stored in a lot (not shown) from the host apparatus 270.

For example, the memory 403 may be embodied by a component such as a flash memory and a HDD (Hard Disk Drive). For example, a process recipe 409 in which information such as process procedures and process conditions of the substrate processing is stored, or a control program 410 for controlling operations of the substrate processing apparatus 100 may be recorded and readably stored in the memory 403. In addition, a first dielectric plate (first dielectric structure) temperature table (“FIRST DPT TABLE” shown in FIG. 3) 411 and a second dielectric plate (second dielectric structure) temperature table (“SECOND DPT TABLE” shown in FIG. 3) 412, which will be described later, are recorded and readably and writably stored in the memory 403.

The process recipe 409 is obtained by combining steps (procedures) of the substrate processing described later such that the controller 400 can execute the steps to acquire a predetermined result, and functions as a program. Hereinafter, the process recipe 409 and the control program 410 may be collectively or individually referred to simply as a “program”. Thus, in the present specification, the term “program” may refer to the process recipe 409 alone, may refer to the control program 410 alone, or may refer to both of the process recipe 409 and the control program 410. The RAM 402 serves as a memory area (work area) in which the program or data read by the CPU 401 are temporarily stored.

The I/O port 404 is connected to the components of the substrate processing apparatus 100 mentioned above such as the gate valve 149, the elevator 218, a pressure regulator (pressure controller) such as the APC 273, a pump such as the DP 275 and the heater controller 223.

The CPU 401 is configured to read and execute the control program 410 from the memory 403 and read the process recipe 409 from the memory 403 in accordance with an instruction such as an operation command inputted from an input/output device 281. The CPU 401 is configured to control various operations, in accordance with contents of the process recipe, such as an opening and closing operation of the gate valve 149, an elevating and lowering operation of the elevator 218, operations of the temperature meters 221 and 237, an operation of the heater controller 323, an on/off control operation of the pump, flow rate adjusting operations of the MFCs mentioned above, and opening and closing operations of the valves mentioned above.

For example, the controller 400 according to the technique of the present embodiment may be embodied by preparing an external memory 282 (for example, a magnetic disk such as a hard disk, an optical disk such as a DVD, a magneto-optical disk such as an MO and a semiconductor memory such as a USB memory) storing the program mentioned above and installing the program onto the computer using the external memory 282. However, a method of providing the program to the computer is not limited to a method using the external memory 282. For example, the program may be directly provided to the computer by a communication interface such as the Internet and a dedicated line instead of the external memory 282. The memory 403 and the external memory 282 may be embodied by a non-transitory computer-readable recording medium. Hereinafter, the memory 403 and the external memory 282 may be collectively or individually referred to as a “recording medium”. Thus, in the present specification, the term “recording medium” may refer to the memory 403 alone, may refer to the external memory 282 alone, or may refer to both of the memory 403 and the external memory 282.

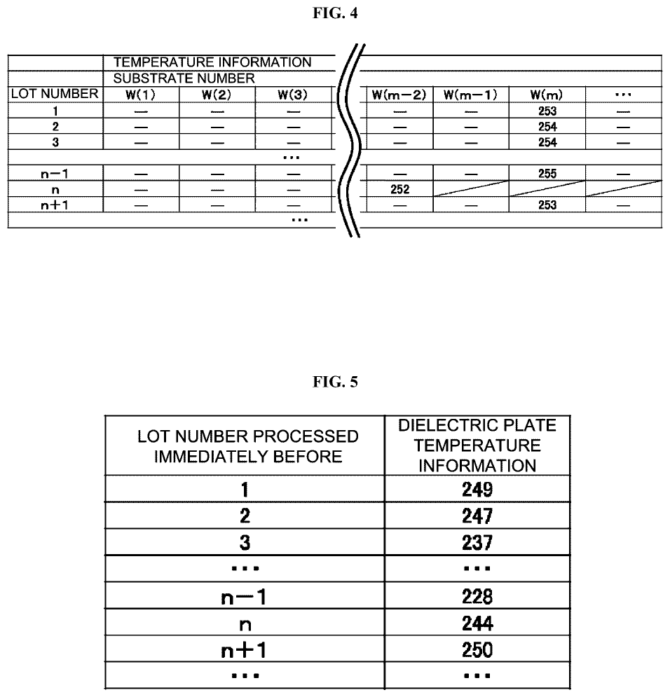

Subsequently, the first dielectric plate temperature table 411 will be described with reference to FIG. 4. A vertical axis in FIG. 4 indicates a lot number, and a horizontal axis in FIG. 4 indicates a temperature of the dielectric plate 252 corresponding to a substrate number. A plurality of substrates including the substrate S may be processed in a certain lot. Hereinafter, the plurality of substrates including the substrate S may also be referred to as “substrates S”. In the first dielectric plate temperature table 411, the temperature of the dielectric plate 252 measured by the temperature meter 237 is recorded.

In the present embodiment, the number of substrates capable of being processed in a single lot is set to m (wherein m is an appropriate natural number). In addition, the number of lots is also set to be greater than “n+1” (wherein n is an appropriate natural number). However, the number of substrates S may vary from lot to lot. For example, “m” substrates S may be included in a first lot, and “m−2” substrates S may be included in an n^{th} lot.

In the first dielectric plate temperature table 411, the temperature of the dielectric plate 252 measured in a first temperature measuring step S104 described later is recorded. In the first temperature measuring step S104, the temperature of the dielectric plate 252 is measured, for example, in a last execution of the substrate processing in a lot related thereto. In other words, the temperature of the dielectric plate 252 is measured in the substrate processing right before a subsequent lot processing setting step S108 described later. In the first lot, it is measured in an m^{th} execution of the substrate processing, and in the n^{th} lot, it is measured in the (m−2)^{th} execution of the substrate processing.

Subsequently, the second dielectric plate temperature table 412 will be described with reference to FIG. 5. Information on the lot number processed immediately before and dielectric plate temperature information corresponding thereto are shown in FIG. 5. The dielectric plate temperature information is temperature information of the dielectric plate 252 measured in a second temperature measuring step S110 described later. In the second dielectric plate temperature table 412, the temperature of the dielectric plate 252 measured by the temperature meter 237 is recorded.

Hereinafter, as a part of a manufacturing process of a semiconductor device, a process (that is, a film forming process) of forming a film on the substrate S using the substrate processing apparatus 100 described above will be described. In the following description, the operations of the components constituting the substrate processing apparatus 100 are controlled by the controller 400.

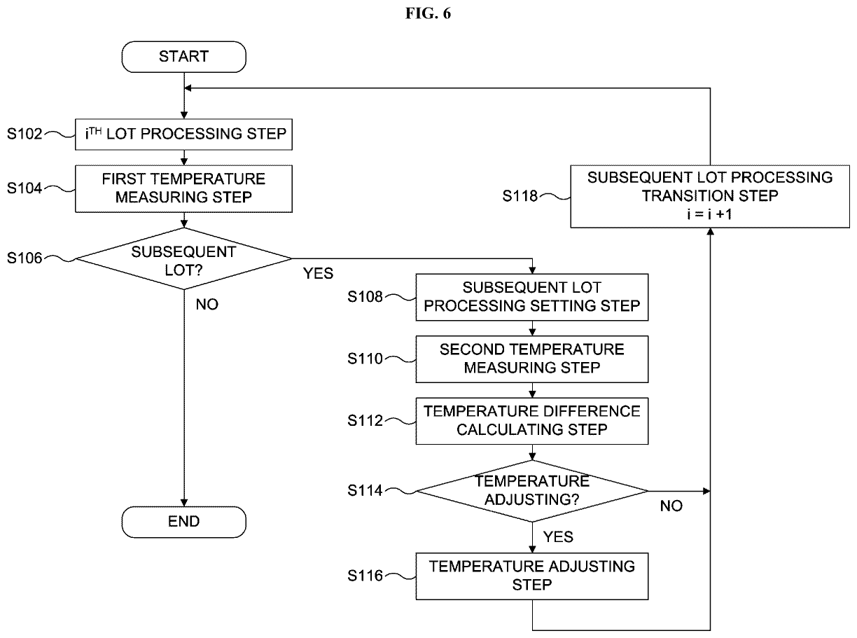

First, the substrate processing for each lot will be described with reference to FIG. 6.

### <i^{th} Lot Processing Step: S102>

The i^{th} lot processing step S102 will be described. In the present step, “i” is an integer of 1 or more. In the i^{th} lot processing step S102, the substrates S in the i^{th} lot are processed. In the present embodiment, in the process space 205, the film forming process is performed sequentially on a predetermined number of substrates S in the i^{th} lot. After the film forming process for the i^{th} lot is completed, to replace a processed substrate S in the i^{th} lot with an unprocessed substrate S in an (i+1)^{th} lot, the processed substrate S in the i^{th} lot is unloaded from the substrate processing apparatus 100 and the unprocessed substrate S in the (i+1)^{th} lot is then loaded into the substrate processing apparatus 100. The film forming process will be described in detail later.

### <First Temperature Measuring Step: S104>

Subsequently, the first temperature measuring step S104 will be described. In the first temperature measuring step S104, the temperature measurer 235 measures the temperature of the dielectric plate 252 during the i^{th} lot processing step S102. The temperature meter 237 records a measurement value measured by the temperature measurer 235 in the first dielectric plate temperature table 411 as reference data.

Subsequently, a timing of measuring the temperature of the dielectric plate 252 will be described. As described above, a plurality of substrates S are processed in the i^{th} lot processing step S102. For example, the present step is performed immediately after a processing of the last substrate in the i^{th} lot. When i is 1, that is, when the film forming process is performed sequentially on the substrates S in the first lot, the temperature is measured immediately after the m^{th} substrate is processed (that is, the m^{th} execution of the substrate processing). When i is n, that is, when the film forming process is performed sequentially on the substrates S in the n^{th} lot, the temperature is measured immediately after the (m−2)^{th} substrate is processed (that is, the (m−2)^{th} execution of the substrate processing). By measuring the temperature at such a timing, it is possible to stably measure the temperature of the dielectric plate 252. For example, the present step may be performed in parallel with the processing of the last substrate in the i^{th} lot.

### <Determination Step: S106>

Subsequently, a determination step S106 will be described. After the i^{th} lot processing step S102 and the first temperature measuring step S104 are completed, the determination step S106 is performed. In the present step, it is determined whether or not a predetermined number of lots are processed. When it is determined that the predetermined number of lots are processed, the substrate processing for each lot is terminated. However, when it is determined that the predetermined number of lots are not processed, the subsequent lot processing setting step S108 is performed.

### <Subsequent Lot Processing Setting Step: S108>

Subsequently, the subsequent lot processing setting step S108 will be described. In the present step, the substrate processing apparatus 100 is set so as to handle a subsequent lot to be processed. For example, when the i^{th} lot is processed, the substrate processing apparatus 100 is set such that an (i+1)^{th} lot can be processed. As an example of such a setting, a transfer robot is switched to be capable of accessing a FOUP (Front Opening Unified Pod) in which substrates S of the (i+1)^{th} lot are stored.

In the present step, since the substrates S in the i^{th} lot are already unloaded from the substrate processing apparatus 100, the substrate support table 212 is in a standby state at the transfer position. In addition, the subsequent lot processing setting step S108 may also be simply referred to as a “setting step”.

### <Second Temperature Measuring Step: S110>

Subsequently, the second temperature measuring step S110 will be described. After the subsequent lot processing setting step S108, the second temperature measuring step S110 is performed. Specifically, the temperature of the dielectric plate 252 is measured immediately before the substrate S in the subsequent lot is loaded. In the present step, the temperature meter 237 records a measurement value measured by the temperature measurer 235 in the second dielectric plate temperature table 412.

As described above, in the subsequent lot processing setting step S108, the substrate support table 212 is in the standby state at the transfer position. Therefore, the dielectric plate 252 is less affected by the heater 213. As a result, the temperature of the dielectric plate 252 measured in the second temperature measuring step S110 is lower than the temperature of the dielectric plate 252 recorded in the first dielectric plate temperature table 411. In addition, as possible reasons for a variation in an amount of a temperature decrease, for example, it may be considered that time varies in the subsequent lot processing setting step S108, or that a variation exists in the temperature in the previous lot, that is, the i^{th} lot.

### <Temperature Difference Calculating Step: S112>

Subsequently, a temperature difference calculating step S112 will be described. In the present embodiment, the term “temperature difference” may refer to a temperature difference (Δt) between the temperature measured in the first temperature measuring step S104 and the temperature measured in the second temperature measuring step S110.

For example, the difference between the temperature at a lot number “n” in the first dielectric plate temperature table 411 and the temperature (which is measured immediately before the substrate S in the subsequent lot is loaded) at the lot number “n” in the second dielectric plate temperature table 412 is calculated.

### <Determination Step: S114>

Subsequently, a determination step S114 will be described. When the temperature of the dielectric plate 252 is lowered, it is considered that a temperature decrease of the dielectric plate 252 may affect a reproducibility of the substrate processing. For example, it is considered that the temperature of the dielectric plate 252 may be different between the last substrate processed in the substrate processing of the i^{th} lot and the first substrate processed in the substrate processing of the (i+1)^{th} lot.

The temperature of the dielectric plate 252 affects a plasma generation state. Thus, when the temperature of the dielectric plate 252 varies, a state of a plasma state may vary as well. In addition, when the temperature at a surface of the dielectric plate 252 is not uniform, for example, when the temperature is different between a center 252C and an edge 252E of the dielectric plate 252, the plasma generated below the center 252C of the dielectric plate 252 and the plasma generated below the edge 252E may be in different states, such as a plasma density and a plasma activity.

Due to such an effect, when the substrate S is processed at different temperatures, it is considered that a film quality (that is, a quality of the film) of the substrate S may vary. Therefore, according to the present embodiment, a temperature adjusting step S116 described later is performed.

In the present step, it is determined whether to proceed to the temperature adjusting step S116. In the present step, the temperature difference calculated in the temperature difference calculating step S112 is used to perform such a determination. For example, when Δt is within a predetermined range (for example, less than 5° C.), that is, when the temperature of the dielectric plate 252 is higher than a predetermined temperature, it is determined that the temperature variation does not affect the substrate processing, and it is determined not to proceed to the temperature adjusting step S116 described later. When it is determined not to proceed to the temperature adjusting step S116, a subsequent lot processing transition step S118 is performed. In the subsequent lot processing transition step S118, i is increased by one, and the i^{th} lot processing step S102 is performed with i increased, and the processing of the substrate S in the i^{th} lot with i increased is started.

For example, when Δt is outside the predetermined range (that is, for example, when Δt is 5° C. or more), that is, when the temperature of the dielectric plate 252 is equal to or lower than the predetermined temperature, it is determined to proceed to the temperature adjusting step S116, and the temperature adjusting step S116 is performed.

### <Temperature Adjusting Step: S116>

Subsequently, the temperature adjusting step S116 will be described. As described above, when switching to the subsequent lot, the temperature of the dielectric plate 252 is lowered. Thus, a processing status of the substrate S to be processed thereafter differs from that of the previous lot. Therefore, in the present step, the temperature of the dielectric plate 252 is adjusted to the same temperature as that of the previous lot. Specifically, a heating process is performed to heat the dielectric plate 252. A specific method is described below.

In the present step, the heating medium is supplied through the gas supplier toward the dielectric plate 252. For example, the inert gas is supplied through the third gas supplier 243. Subsequently, the microwave is supplied from the microwave supply source 257 to the vessel 251, and the plasma of the heating medium (inert gas) is generated on the surface of the dielectric plate 252 facing the process space 205. A heat of the plasma generated as described above heats the dielectric plate 252.

Subsequently, a comparative example of a heating method will be described. As a heating structure of the comparative example, for example, a resistance heater may be disposed on an outer periphery of the dielectric plate 252. However, with such a structure, the center 252C of the dielectric plate 252 is far from the resistance heater. As a result, the temperature of the edge 252E of the dielectric plate 252 becomes higher than that of the center 252C of the dielectric plate 252. Thereby, a surface temperature of the dielectric plate 252 may be not uniform, and therefore, the plasma generated by the dielectric plate 252 may be not uniform.

In contrast, when the heating medium is used, the heating medium can be uniformly supplied to the surface of the dielectric plate 252. Thereby, no temperature difference occurs between the center 252C and the edge 252E of the dielectric plate 252. As a result, since the dielectric plate 252 can be uniformly heated, it is possible to uniformly generate the plasma.

### <Subsequent Lot Processing Transition Step: S118>

Subsequently, the subsequent lot processing transition step S118 will be described. When the temperature adjusting step S116 is completed, or when it is determined not to proceed to the temperature adjusting step S116 in the determination step S114, the subsequent lot processing transition step S118 is performed. In the present step, the substrate processing apparatus 100 is controlled based on the setting of the subsequent lot processing setting step S108. For example, the substrate S of the subsequent lot is loaded into the substrate processing apparatus 100. As described above, i is increased by one, and the i^{th} lot processing step S102 is performed with i increased.

### <Film Forming Step>

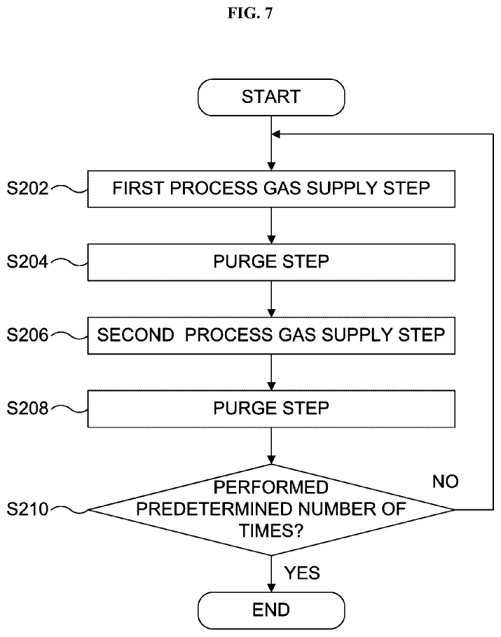

Subsequently, as a part of the manufacturing process of the semiconductor device, a step (film forming step) of forming the film on the substrate S using the substrate processing apparatus 100 with the configuration mentioned above will be described with reference to FIG. 7. The present step is a step of performing the substrate processing for a single substrate in the i^{th} lot processing step S102. That is, in the i^{th} lot processing step S102, the film forming step is repeatedly performed in accordance with the number of the substrates in the lot.

The present step will be described by way of an example in which the DCS gas is used as a first process gas and the NH₃ gas is used as a second process gas, and a silicon nitride film (SiN film) is formed as a semiconductor film on the substrate S by alternately supplying the DCS gas and the NH₃ gas.

### <Substrate Loading and Supporting Step>

The substrate support table 212 is lowered to the transfer position of the substrate S, and the lift pins 207 are inserted into the through-holes 214 of the substrate support table 212. As a result, the lift pins 207 protrude a predetermined height from the surface of the substrate support table 212. In parallel with the operations mentioned above, an atmosphere (inner atmosphere) of the transfer space 206 is exhausted to a pressure equal to or lower than that of a vacuum transfer chamber (not shown) adjacent thereto.

Subsequently, the gate valve 149 is opened to communicate the transfer space 206 to the vacuum transfer chamber adjacent thereto. Then, the substrate S is supported on the lift pins 207 from the vacuum transfer chamber using a vacuum transfer robot (not shown).

### <Moving to Substrate Processing Position Step>

After a predetermined time has elapsed, the substrate support table 212 is elevated to support the substrate S on the support surface 211, and is further elevated to the substrate processing position as shown in FIG. 1.

### <Gas Supply Step>

Subsequently, the film forming step will be described. The film forming step will be describe in detail below with reference to FIG. 7. In addition, as the film forming step, for example, a cyclic process is performed. In the cyclic process, a step of alternately supplying different process gases is repeatedly performed.

### <First Process Gas Supply Step: S202>

When the substrate support table 212 is moved to the substrate processing position, an atmosphere (inner atmosphere) of the process chamber 201 is exhausted from the process chamber 201 through the exhaust pipe 272 to adjust a pressure (inner pressure) of the process chamber 201.

When a temperature of the substrate S reaches a predetermined temperature (for example, within a range from 500° C. to 600° C.) while adjusting the inner pressure of the process chamber 201 to a predetermined pressure, the DCS gas is supplied through the gas supply pipe 240 to the process chamber 201. By supplying the DCS gas, a silicon-containing layer is formed on the substrate S. After a predetermined time has elapsed, a supply of the DCS gas is stopped.

### <Purge Step: S204>

After the supply of the DCS gas is stopped, by supplying the N₂ gas through the third gas supply pipe 243a, the inner atmosphere of the process chamber 201 is purged. As a result, the DCS gas that was not bonded to the substrate S in the first process gas supply step S202 is removed from the process chamber 201 through the exhaust pipe 272.

### <Second Process Gas Supply Step: S206>

When the purge of the inner atmosphere of the process chamber 201 is completed, the second process gas supply step S206 is performed. In the second process gas supply step S206, the valve 242d is opened to start a supply of the NH₃ gas. In the present step, the MFC 242c is adjusted such that a flow rate of the NH₃ gas is set to be a predetermined flow rate. For example, a supply flow rate of the NH₃ gas is set to be within a range from 1,000 sccm to 10,000 sccm. In addition, by supplying the microwave to the vessel 251, it is possible to generate the plasma of the NH₃ gas in the process space 205.

The plasma of the NH₃ gas reacts with the silicon-containing layer on the substrate S. Thereby, the silicon-containing layer already formed on the substrate S is modified by the plasma of the NH₃ gas. As a result, for example, a silicon nitride layer (SiN layer) serving as a layer containing silicon and nitrogen elements is formed on the substrate S. After a predetermined time has elapsed from the supply of the NH₃ gas is started, the supply of the NH₃ gas is stopped.

### <Purge Step: S208>

After the supply of the NH₃ gas is stopped, a purge step S208 substantially the same as the purge step S204 described above is performed. The operations of the components in the purge step S208 are substantially the same as in the purge step S204 described above. Therefore, the description of the purge step S208 will be omitted.

### <Determination Step: S210>

The controller 400 determines whether a cycle (which is constituted by the first process gas supply step S202, the purge step S204, the second process gas supply step S206 and the purge step S208 mentioned above) is performed a predetermined number of times (x times, wherein x is an integer equal to or greater than 1). By performing the cycle the predetermined number of times, it is possible to form the silicon nitride layer with a desired film thickness on the substrate S.

### <Substrate Unloading Step>

After the silicon nitride layer with the desired film thickness is formed, the substrate support table 212 is lowered such that the substrate S is moved to the transfer position. After moving the substrate S to the transfer position, the substrate S is unloaded from the transfer space 206.

In a manner described above, by maintaining the temperature of the dielectric plate 252 within a predetermined range between lots, it is possible to process the substrates S uniformly between the lots. In addition, by heating the dielectric plate 252 with the heating medium, it is possible to uniformly heat the surface of the dielectric plate 252. Therefore, it is possible to uniformize the film quality between the lots (more specifically, between the substrates S).

### Second Embodiment of the Present Disclosure

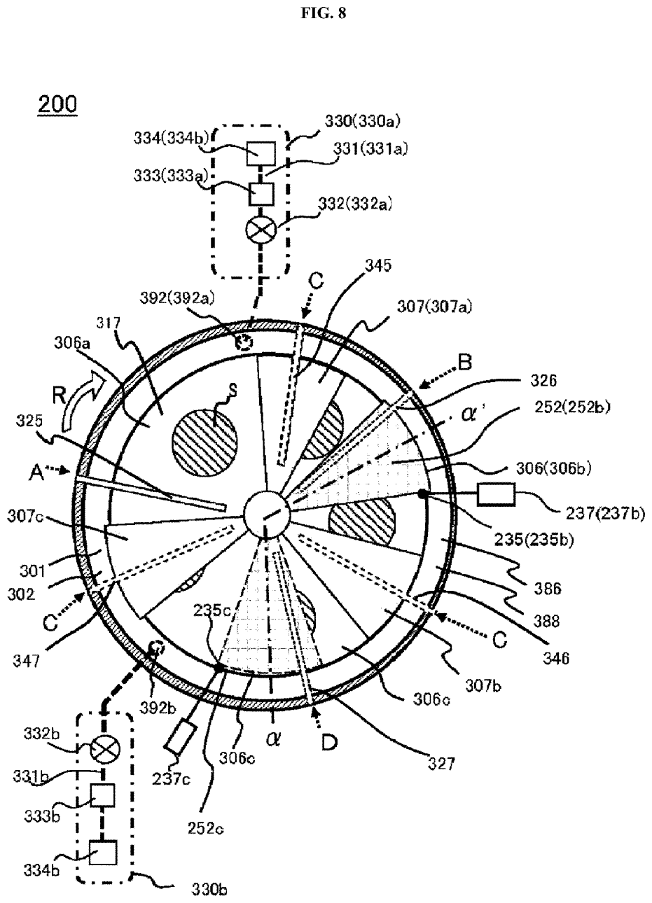

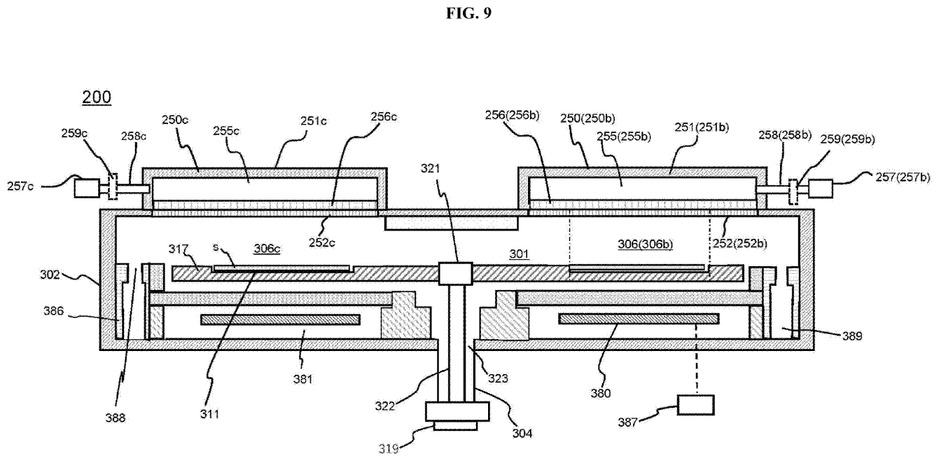

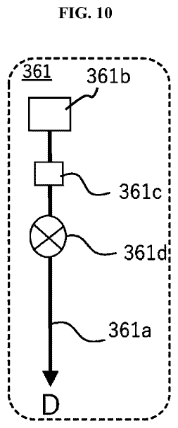

Subsequently, a second embodiment of the technique of the present disclosure will be described mainly with reference to FIGS. 8 to 10. FIG. 8 is a diagram schematically illustrating a horizontal-cross section of a substrate processing apparatus 200 when viewed from above. FIG. 9 is a diagram schematically illustrating a vertical cross-section of the substrate processing apparatus 200, and more specifically, a cross-section of a chamber 302 shown in FIG. 8 taken along a line α-α′. The line α-α′ is directed from a toward α′ via the center of the chamber 302. FIG. 10 is a diagram schematically illustrating an exemplary configuration of a fourth gas supplier (which is a fourth gas supply structure) 361 provided in the substrate processing apparatus 200.

A specific configuration of the substrate processing apparatus 200 will be described. The substrate processing apparatus 200 is controlled by the controller 400, similar to the substrate processing apparatus 100. In FIG. 9, substantially the same components as those of the first embodiment described with reference to FIG. 1 will be denoted by like reference numerals, and detailed descriptions thereof will be omitted.

As shown in FIGS. 8 and 9, the substrate processing apparatus 200 is constituted mainly by the chamber 302 which is an airtight sealed vessel of a cylindrical shape. A process chamber 301 in which the substrate S is processed is provided in the chamber 302. A gate valve (not shown) is connected to the chamber 302. The substrate S is loaded (transferred) into or unloaded (transferred) out of the chamber 302 through the gate valve.

In the process chamber 301, a process region (process area) 306 (which includes a first process region 306a, a second process region 306b and a third process region 306c) serving as a process space to which the process gas is supplied and a purge region (purge area) 307 (which includes a first purge region 307a, a second purge region 307b and a third purge region 307c) to which the purge gas is supplied are provided. According to the present embodiments, the process region 306 and the purge region 307 are alternately arranged along a circumferential direction of the process chamber 301. For example, the first process region 306a, the first purge region 307a, the second process region 306b, the second purge region 307b, the third process region 306c and the third purge region 307c are sequentially arranged along the circumferential direction in this order.

A nozzle 325 to which the first gas supplier 241 is connected is provided in the first process region 306a, a nozzle 326 to which the second gas supplier 242 is connected is provided in the second process region 306b, and a nozzle 327 to which the fourth gas supplier 361 described later is connected is provided in the third process region 306c. In addition, a nozzle 345 is provided in the first purge region 307a, a nozzle 346 is provided in the second purge region 307b and a nozzle 347 is provided in the third purge region 307c. The third gas supplier 243 is connected to each of the nozzles 345, 346 and 347.

Subsequently, the fourth gas supplier 361 will be described with reference to FIG. 10. A fourth gas supply source 361b, an MFC 361c and a valve 361d are sequentially provided at a fourth gas supply pipe 361a in this order from an upstream side toward a downstream side of the fourth gas supply pipe 361a in the gas flow direction.

The fourth gas supply source 361b is a source of a fourth gas (hereinafter, also referred to as a “fourth element-containing gas”) containing a fourth element. The fourth element-containing gas is one of the process gases. For example, the fourth element-containing gas may serve as the reactive gas or the modifying gas.

The fourth element is, for example, hydrogen (H). In the technique of the present disclosure, for example, the fourth element-containing gas is a hydrogen-containing gas. Specifically, as the hydrogen-containing gas, hydrogen (H₂) gas may be used. The fourth gas supplier 361 is constituted mainly by the fourth gas supply pipe 361a, the MFC 361c and the valve 361d. The fourth gas supplier 361 may also be referred to as a “second reactive gas supplier” which is a second reactive gas supply structure.

The first gas is supplied through the nozzle 325 into the first process region 306a, the second gas is supplied through the nozzle 326 into the second process region 306b, and the fourth gas is supplied through the nozzle 327 into the third process region 306c. In addition, the inert gas is also supplied through the nozzle 345 into the first purge region 307a, through the nozzle 346 into the second purge region 307b and through the nozzle 347 into the third purge region 307c. As a result, a predetermined processing is performed on the substrate S in accordance with the gas supplied into each region.

The purge region 307 is a region that spatially separates the first process region 306a, the second process region 306b and the third process region 306c. By supplying the purge gas to the spaces described above, it is possible to partition adjacent process regions (that is, the first process region 306a, the second process region 306b and the third process region 306c).

In a central portion of the chamber 302, a substrate support plate 317 is provided. The substrate support plate 317 serves as a substrate support provided with a rotation axis at a center of the chamber 302 and configured to be rotatable. The substrate support plate 317 is made of a material capable of allowing a transmission of a heat, and is configured to transmit the heat radiated from a heater 380 serving as a heating structure described later. The substrate S is heated by the heat transmitted through the substrate support plate 317.

The substrate support plate 317 is provided with a plurality of support surfaces 311 such that a plurality of substrates S (for example, five substrates) can be arranged on the same plane and along the same circumference along a rotation direction. The substrates S are supported on the support surfaces 311, respectively. The substrate support plate 317 may also be referred to as a “support” which is a support structure because the substrate support plate 317 is configured to support the substrates S.

The substrate support plate 317 is supported by a shaft 322 through a core structure 321. A lower portion of the shaft 322 passes through a hole 323 provided in a lower portion (bottom) of the chamber 302, and a bellows 304 provided outside the chamber 302 and capable of airtightly (hermetically) sealing the chamber 302 covers the lower portion of the shaft 322. In addition, a rotator (which is a rotating structure) 319 is provided at a lower end of the shaft 322. The rotator 319 is configured to be capable of rotating the substrate support plate 317 in accordance with an instruction from the controller 400.

A heater structure 381 with the heater 380 serving as the heating structure (embedded therein) is disposed below the substrate support plate 317. The heater 380 is configured to heat each of the substrates S placed on the substrate support plate 317. The heater 380 is provided in the circumferential direction in accordance with a shape of the chamber 302. A heater controller 387 is connected to the heater 380. The heater controller 387 is electrically connected to the controller 400, and is configured to control a supply of the electric power to the heater 380 in accordance with an instruction from the controller 400 to perform a temperature control.

An exhaust structure 386 is disposed at an outer periphery of the substrate support plate 317. The exhaust structure 386 includes an exhaust groove 388 and an exhaust buffer space 389. Each of the exhaust groove 388 and the exhaust buffer space 389 is arranged in the circumferential direction in accordance with the shape of the chamber 302. An exhaust hole 392 is provided at a bottom of the exhaust structure 386. The gases supplied into the chamber 302 are exhausted through the exhaust hole 392. Each of the gases is exhausted through the exhaust hole 392 via the exhaust groove 388 and the exhaust buffer space 389.

The exhaust hole 392 is configured to be in communication with an exhauster (which is an exhaust structure) 330. The exhauster 330 includes an exhaust pipe 331, and a valve 332 and a pressure regulator (pressure adjusting structure) 333 are provided at the exhaust pipe 331. A pump 334 is connected to the exhaust pipe 331. The exhauster 330 is constituted mainly by the exhaust pipe 331 and the valve 332. The exhauster 330 may further include the pressure regulator 333 and the pump 334. The exhauster 330 may be provided for each of exhaust holes 392 as shown in FIG. 8. In such a case, an exhauster communicating with an exhaust hole 392a may also be referred to as an “exhauster 330a”, and an exhauster communicating with an exhaust hole 392b may also be referred to as an “exhauster 330b”.

Subsequently, the electromagnetic wave supplier 250 according to the present embodiment will be described. A configuration of the electromagnetic wave supplier 250 according to the present embodiment is substantially the same as that of the electromagnetic wave supplier 250 mounted on the substrate processing apparatus 100. The electromagnetic wave supplier 250 is provided above each of the second process region 306b and the third process region 306c, and is configured to generate the plasma in each region. The electromagnetic wave supplier 250 above the second process region 306b may also be referred to as an “electromagnetic wave supplier 250b”, and the electromagnetic wave supplier 250 above the third process region 306c may also be referred to as an “electromagnetic wave supplier 250c”. Similarly, each component of the electromagnetic wave supplier 250 related to the second process region 306b is labeled with a symbol “b”, and each component of the electromagnetic wave supplier 250 related to the third process region 306c is labeled with a symbol “c”. Similarly, each of the dielectric plate 252, the temperature measurer 235 and the temperature meter 237 related to the second process region 306b or related to the third process region 306c is labeled with the symbol “b” or “c”. In addition, the slot plate 256 corresponding to a dielectric plate 252b is labeled with the symbol “b”, and the slot plate 256 corresponding to a dielectric plate 252c is labeled with the symbol “c”. The vessel 251 corresponding to the electromagnetic wave supplier 250b is labeled with the symbol “b”, and the vessel 251 corresponding to the electromagnetic wave supplier 250c is labeled with the symbol “c”. The space 255 corresponding to a vessel 251b is labeled with the symbol “b”, and the space 255 corresponding to a vessel 251c is labeled with the symbol “c”. The same also applies to the microwave supply source 257, the waveguide 258 and a shutter 259.

The chamber 302 is provided with the nozzles through which the gas is supplied toward the dielectric plate 252 from below the dielectric plate 252. Specifically, in the second process region 306b, the nozzle 326 is provided below the dielectric plate 252b. In addition, in the third process region 306c, the nozzle 327 is provided below the dielectric plate 252c. The nozzle 326 is configured to communicate with the second gas supplier 242. The nozzle 327 is configured to communicate with the fourth gas supplier 361.

Subsequently, the substrate processing according to the present embodiment will be described. The substrate processing according to the present embodiment is substantially the same as that of the first embodiment. Therefore, features different from those of the first embodiment will be mainly described.

### <i^{th} Lot Processing Step: S102>

In the i^{th} lot processing step S102 according to the present embodiment, the substrates S in the i^{th} lot are processed. In the present embodiment, in the process region 306, the film forming process is performed sequentially on a predetermined number of substrates S in the i^{th} lot. Specifically, by rotating the substrate support plate 317 with the plurality of substrates S supported on the support surfaces 311, the substrate S is passed through the first process region 306a, the second process region 306b and the third process region 306c.

The first process gas supply step according to the present embodiment is performed by passing the substrate S through the first process region 306a in a state where the first gas (for example, the DCS gas) is supplied, and the second process gas supply step according to the present embodiment is performed by passing the substrate S through the second process region 306b in a state where the plasma of the second gas (for example, the NH₃ gas) is generated in the second process region 306b. By performing the steps mentioned above a predetermined number of times, that is, after passing the substrate S through the regions mentioned above the predetermined number of times, the silicon nitride film is formed on the substrate S. When the silicon nitride film is to be further modified, with the supply of the first gas and the supply of second gas stopped, by passing the substrate S through the third process region 306c in a state where the fourth gas (H₂ gas) is in a plasma state, it is possible to modify the silicon nitride film. Specifically, impurities (such as chlorine (Cl) component) contained in the silicon nitride film formed by the first gas and the second gas are desorbed by the hydrogen (H) plasma.

### <First Temperature Measuring Step: S104>

The first temperature measuring step S104 according to the present embodiment is substantially the same as that of the first embodiment, except that the temperature of each of the dielectric plates 252b and 252c is measured. Specifically, a temperature measurer 235b measures a temperature of the dielectric plate 252b, and a temperature measurer 235c measures a temperature of the dielectric plate 252c.

### <Determination Step: S106 and Subsequent Lot Processing Setting Step: S108>

Since the determination step S106 and the subsequent lot processing setting step S108 according to the present embodiment are substantially the same as those of the first embodiment, the description thereof will be omitted.

### <Second Temperature Measuring Step: S110>

The second temperature measuring step S110 according to the present embodiment is substantially the same as that of the first embodiment, except that the temperature of each of the dielectric plates 252b and 252c is measured. Specifically, the temperature measurer 235b measures the temperature of the dielectric plate 252b, and the temperature measurer 235c measures the temperature of the dielectric plate 252c.

### <Temperature Difference Calculating Step: S112>

In the present step, a difference between the temperature of each of the dielectric plates 252b and 252c measured in the first temperature measuring step S104 and the temperature of each of the dielectric plates 252b and 252c measured in the second temperature measuring step S110 is calculated. Specifically, the temperature difference (Δt) between the dielectric plate 252b and the dielectric plate 252c is calculated.

### <Determination Step: S114>

When the temperature difference (Δt) in each of the dielectric plates 252b and 252c is within a predetermined range (for example, less than 5° C.), it is determined not to proceed to the temperature adjusting step S116 according to the present embodiment, and the subsequent lot processing transition step S118 according to the present embodiment is performed. When the temperature difference (Δt) of at least one among the dielectric plates 252b and 252c is outside the predetermined range (that is, for example, when Δt is 5° C. or more), that is, when the temperature of the dielectric plate 252 is equal to or lower than the predetermined temperature, it is determined to proceed to the temperature adjusting step S116, and the temperature adjusting step S116 is performed.

Examples of conditions are shown below. However, the conditions may vary depending on processing contents, and are not limited to such examples.
Dielectric plate 252b: Δt (252b)<5° C.
Dielectric plate 252c: Δt (252c)<5° C.

### <Temperature Adjusting Step: S116>

Subsequently, the temperature adjusting step S116 according to the present embodiment will be described. In the present step, the temperature is adjusted for each of the dielectric plates 252b and 252c. When adjusting the temperature, the same process as in the first embodiment is performed for each of the dielectric plates 252b and 252c. Specifically, first, the inert gas is supplied through the nozzles 346 and 347 such that the inert gas serving as the heating medium is present below the dielectric plate 252b and the dielectric plate 252c. Subsequently, the microwave is supplied from the microwave supply source 257b to the vessel 251b such that the plasma of the inert gas is generated on a surface of the dielectric plate 252b facing the process region 306b. Similarly, the microwave is supplied from the microwave supply source 257c to the vessel 251c such that the plasma of the inert gas is generated on a surface of the dielectric plate 252c facing the process region 306c. The heat of the plasma generated as described above heats the dielectric plates 252b and 252c. By heating the dielectric plates 252b and 252c in a manner described above, it is possible to uniformly heat the surfaces of the dielectric plates 252b and 252c.

After heating the dielectric plates 252b and 252c, the temperature of each of the dielectric plates 252b and 252c is compared with the temperature of each of the dielectric plates 252b and 252c measured in the first temperature measuring step S104. When the temperature difference therebetween is within a predetermined range, that is, after a target temperature is reached, the subsequent lot processing transition step S118 according to the present embodiment is performed. By adjusting (or setting) the temperature difference between the present step and the first temperature measuring step S104 within the predetermined range for each of the dielectric plates 252b and 252c, it is possible to set the plasma generation state of each of the dielectric plates 252b and 252c substantially the same as that of the previous lot. In particular, when the electromagnetic wave supplier 250b and the electromagnetic wave supplier 250c generate the plasma at different timings as in the present embodiment, the temperatures of the dielectric plates 252b and 252c may be different. Therefore, it is preferable to adjust the temperatures individually.

When adjusting the temperature of each of the dielectric plates 252b and 252c individually, it is preferable to adjust a radiation time of supplying the microwave. Since a supply time of the microwave and a plasma generation time are related, it is possible to adjust the temperature of each of the dielectric plates 252b and 252c individually by adjusting the supply time of the microwave individually. The radiation time is adjusted by turning the microwave supply source 257 on and off. In addition, when the shutter 259 serving as a movement limiting structure configured to restrict (or limit) a movement of the microwave is provided in the waveguide 258, the radiation time may be adjusted by turning the shutter 259 on and off.

It is preferable that the support surface 311 is not maintained (or located) directly below the dielectric plate 252 in at least a part of a period during which the plasma of the heating medium (that is, the inert gas) is generated. To achieve such a state, the dielectric plate 252 and the support surface 311 are moved relative to each other. Specifically, by rotating the substrate support plate 317, the support surface 311 is moved from below the dielectric plate 252. When the substrate support plate 317 is fixed without rotated, the same support surface 311 may be always located directly below the dielectric plate 252. Therefore, when the energy of the plasma is strong, the support surface 311 may be etched. When such an etching occurs, since a state of the support surface 311 is different from a state of the other support surfaces 311, a heating state of the heater 380 may be non-uniform across an entirety of the substrate support plate 317, or particles may be generated by such an etching. In contrast, by rotating the substrate support plate 317 at least in a part of a plasma generating structure, a specific surface of the substrate support plate 317 is not always located directly below the dielectric plate 252. As a result, it is possible to constantly maintain the state of the support surface 311 on the substrate support plate 317.

In a manner described above, it is possible to uniformize the film quality between the lots (more specifically, between the substrates S).

### Third Embodiment of the Present Disclosure

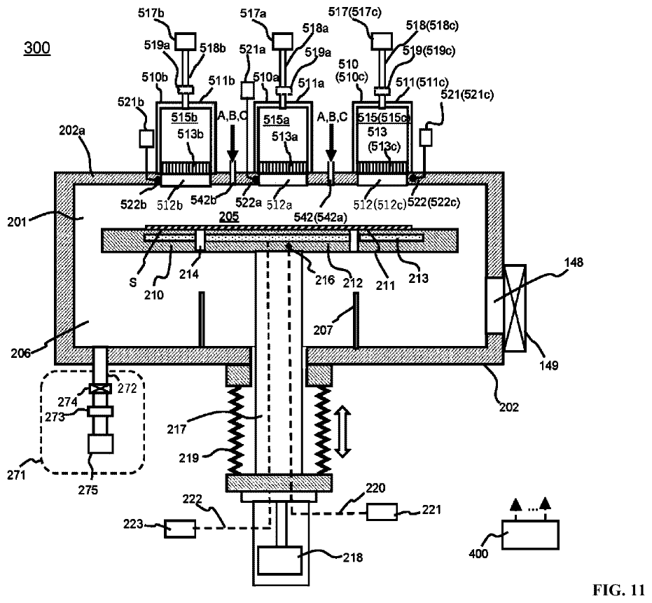

Subsequently, a third embodiment of the technique of the present disclosure will be described mainly with reference to FIG. 11. The third embodiment differs from the first embodiment mainly in that a plurality of dielectric plates (dielectric structures) 512, a plurality of electromagnetic wave suppliers 510 and a plurality of temperature meters 521 are provided. Hereinafter, each of the dielectric plates 512, each of the electromagnetic wave suppliers 510, and each of the temperature meters 521 may also be referred to as a “dielectric plate 512”, as an “electromagnetic wave supplier 510” and as a “temperature meter 521”, respectively. Hereinafter, features different from those of the first embodiment will be mainly described. In FIG. 11, substantially the same components as those of the first embodiment described with reference to FIG. 1 will be denoted by like reference numerals, and detailed descriptions thereof will be omitted.

A relationship among the dielectric plate 512, the electromagnetic wave supplier 510 and the temperature meter 521 will be described. In FIG. 11, three combinations of the dielectric plate 512, the electromagnetic wave supplier 510 and the temperature meter 521 are shown. However, configurations of the three combinations are substantially the same, one of the three combinations will be described as an example.

A substrate processing apparatus 300 according to the present embodiment is provided with the plurality of electromagnetic wave suppliers 510. A vessel 511 constituting the electromagnetic wave supplier 510 is provided on the ceiling 202a of the vessel 202. That is, for example, a vessel 511a, a vessel 511b and a vessel 511c are provided. Hereinafter, the vessels 511a, 511b and 511c may be collectively or individually referred to as the “vessel 511”. The plurality of dielectric plates 512 are provided between the vessel 511 and the substrate support table 212. A plurality of slot plates 513 are provided above the dielectric plates 512, respectively. Hereinafter, each of the slot plates 513 may also be referred to as a “slot plate 513”. A plurality of temperature measurers 522 capable of measuring temperatures of the dielectric plates 512, respectively, are provided in the vicinity of the dielectric plates 512, for example, on the ceiling 202a. Hereinafter, each of the temperature measurers 522 may also be referred to as a “temperature measurer 522”. The temperature measurers 522 are connected to the temperature meters 521, respectively. In addition, although the temperature meters 521 are shown in FIG. 11, the present embodiment is not limited thereto. For example, information measured by each of the temperature measurers 522 may be collected in a single temperature meter 521.

A space 515 is provided between an upper surface of the slot plate 513 and an inner wall of the vessel 511. A waveguide 518 is connected to the vessel 511. A microwave supply source 517 is connected to the waveguide 518, and the microwave generated from the microwave supply source 517 is supplied to the space 515 through the waveguide 518. A shutter 519 may be provided in the waveguide 518. The electromagnetic wave supplier 510 is constituted mainly by the vessel 511. However, the electromagnetic wave supplier 510 may further include at least one among the slot plate 513, the shutter 519 and the microwave supply source 517, or a combination thereof.

Since the electromagnetic wave supplier 510 is provided for each of the dielectric plates 512 in a manner described above, it is possible to heat each of the dielectric plates 512 independently, as described below.

A gas supply pipe 542 capable of supplying the gas below each of the dielectric plates 512 is provided on the ceiling 202a of the vessel 202 between each of the dielectric plates 512. The gas supply pipe 542 may be configured as a pipe as long as the gas can be supplied to the dielectric plate 512, and a plurality of gas supply pipes may be provided as the gas supply pipe 542 as shown in FIG. 11. Hereinafter, the plurality of gas supply pipes mentioned above may also be referred to as “gas supply pipes 542”. For example, two gas supply pipes 542 (542a and 542b) are shown in FIG. 11. The gas supply pipes 542 are configured to communicate with the first gas supplier 241, the second gas supplier 242 and the third gas supplier 243.

Among the plurality of dielectric plates 512, a dielectric plate 512a serving as a first dielectric plate is located at a center of the ceiling 202a, and dielectric plate 512b and 512c serving as a second dielectric plate are arranged in a circumferential direction around the dielectric plate 512a. The center of the ceiling 202a is a position facing a center of the substrate S supported by the support surface 211. By using such an arrangement mentioned above, it is possible to uniformize a temperature at a surface of the substrate S. In FIG. 11, the two dielectric plates 512b and 512c are shown around the dielectric plate 512a. However, three or more dielectric plates may be provided around the dielectric plate 512a.

The electromagnetic wave supplier 510 is provided to correspond to each of the dielectric plates 512. In FIG. 11, the electromagnetic wave supplier 510 and the temperature meter 521 corresponding to the dielectric plate 512a are labeled with the symbol “a”, the electromagnetic wave supplier 510 and the temperature meter 521 corresponding to the dielectric plate 512b are labeled with the symbol “b”, and the electromagnetic wave supplier 510 and the temperature meter 521 corresponding to the dielectric plate 512c are labeled with the symbol “c”. Similarly, the slot plate 513 corresponding to the dielectric plate 512a is labeled with the symbol “a”, the slot plate 513 corresponding to the dielectric plate 512b is labeled with the symbol “b”, and the slot plate 513 corresponding to the dielectric plate 512c is labeled with the symbol “c”. Similarly, the temperature measurer 522 corresponding to a temperature meter 521a is labeled with the symbol “a”, the temperature measurer 522 corresponding to a temperature meter 521b is labeled with the symbol “b”, and the temperature measurer 522 corresponding to a temperature meter 521c is labeled with the symbol “c”. Similarly, the vessel 511 corresponding to an electromagnetic wave supplier 510a is labeled with the symbol “a”, the vessel 511 corresponding to an electromagnetic wave supplier 510b is labeled with the symbol “b”, and the vessel 511 corresponding to an electromagnetic wave supplier 510c is labeled with the symbol “c”. Similarly, the space 515 corresponding to the vessel 511a is labeled with the symbol “a”, the space 515 corresponding to the vessel 511b is labeled with the symbol “b”, and the space 515 corresponding to the vessel 511c is labeled with the symbol “c”. The same also applies to the microwave supply source 517, the waveguide 518 and the shutter 519.

Subsequently, the substrate processing according to the present embodiment will be described. The substrate processing according to the present embodiment is substantially the same as that of the first embodiment. Therefore, features different from those of the first embodiment will be mainly described.

### <i^{th} Lot Processing Step: S102>

In the i^{th} lot processing step S102 according to the present embodiment, the substrates S in the i^{th} lot are processed. In the present embodiment, in the process space 205, the film forming process is performed sequentially on a predetermined number of substrates S in the i^{th} lot. Specifically, the plasma is generated in the process space 205 by the plurality of electromagnetic wave suppliers 510, and the substrates S are processed.

### <First Temperature Measuring Step: S104>

The first temperature measuring step S104 according to the present embodiment is substantially the same as that of the first embodiment, except that the temperature of each of the dielectric plates 512, that is, a temperature of each of the dielectric plates 512a, 512b and 512c is measured. Specifically, a temperature measurer 522a measures the temperature of the dielectric plate 512a, a temperature measurer 522b measures the temperature of the dielectric plate 512b, and a temperature measurer 522c measures the temperature of the dielectric plate 512c.

### <Determination Step: S106 and Subsequent Lot Processing Setting Step: S108>

Since the determination step S106 and the subsequent lot processing setting step S108 according to the present embodiment are substantially the same as those of the first embodiment, the description thereof will be omitted.

### <Second Temperature Measuring Step: S110>

Similar to the first temperature measuring step S104, the temperature of each of the dielectric plates 512 is measured. Specifically, the temperature measurer 522a measures the temperature of the dielectric plate 512a, the temperature measurer 522b measures the temperature of the dielectric plate 512b, and the temperature measurer 522c measures the temperature of the dielectric plate 512c.

### <Temperature Difference Calculating Step: S112>

In the present step, a temperature difference in each of the dielectric plates 512 is calculated. Specifically, for each of the dielectric plates 512a, 512b and 512c, the temperature difference between the temperature measured in the first temperature measuring step S104 and the temperature measured in the second temperature measuring step S110 is calculated.

### <Determination Step: S114>

When the following conditions are satisfied in a relationship with each of the dielectric plates 512, the subsequent lot processing transition step S118 is performed without proceeding to the temperature adjusting step S116. A first condition is that the temperature difference between the first temperature measuring step S104 and the second temperature measuring step S110 of each of the dielectric plates 512 is within a first range (predetermined range). For example, when the temperature difference between the first temperature measuring step S104 and the second temperature measuring step S110 of the dielectric plate 512a is within the first range, the first condition is met for the dielectric plate 512a. The same also applies to the dielectric plates 512b and 512c. The second condition is that the temperature difference between each of the dielectric plates 512 in the second temperature measuring step S110 is within a second range (predetermined range). For example, when the temperature difference between the dielectric plates 512a, 512b and 512c in the second temperature measuring step S110 is within the second range, the second condition is met. When either the first condition or the second condition is not met, the temperature adjusting step S116 is performed. When the temperature difference between at least one among the dielectric plates 512 is outside the predetermined range (for example, 5° C. or more), that is, when the temperature of the dielectric plate 512 is equal to or lower than the predetermined temperature, it is determined that the temperature adjusting step S116 is to be performed, and then, the temperature adjusting step S116 is performed.

### <Temperature Adjusting Step: S116>

Subsequently, the temperature adjusting step S116 according to the present embodiment will be described. When the conditions mentioned above are not met, the temperature adjusting step S116 is performed. In the present step, the temperature is adjusted for each of the dielectric plates 512. In a manner described above, it is possible to appropriately adjust the temperature for each of the dielectric plates 512.

First, the inert gas is supplied through the gas supply pipe 542 such that the inert gas serving as the heating medium is present below the dielectric plate 512a, the dielectric plate 512b, and the dielectric plate 512c. Subsequently, the microwave is supplied from a microwave supply source 517a to the vessel 511a such that the plasma of the inert gas is generated on a surface of the dielectric plate 512a facing the process space 205. The heat of the plasma generated as described above heats the dielectric plate 512a. The dielectric plates 512b and 512c are also heated in the same manner.

After heating the dielectric plates 512, when the conditions mentioned above are met, that is, after each of the dielectric plates 512 reaches the target temperature, the subsequent lot processing transition step S118 according to the present embodiment is performed. By adjusting (or setting) the temperature difference between the present step and the first temperature measuring step S104 within the first range (predetermined range) for each of the dielectric plates 512, it is possible to set the plasma generation state of each of the dielectric plates 512 substantially the same as that of the previous lot. In addition, by adjusting (or setting) the temperature difference between the present step and the first temperature measuring step S104 within the second range (predetermined range) for each of the dielectric plates 512, it is possible to uniformize the plasma generation state of each of the dielectric plates 512.

However, the temperature measured in the second temperature measuring step S110 for each of the dielectric plates 512 may vary. For example, due to a positional relationship with the exhauster 271, the temperature may vary. As shown in FIG. 11, when the exhauster 271 is configured to exhaust the inner atmosphere of the process space 205 from the outer periphery of the substrate support 210, a gas flow velocity below the dielectric plate 512b in the vicinity of the outer periphery of the substrate support 210 is greater than a gas flow velocity at a center of the substrate support 210. Therefore, when exhausting the inner atmosphere of the process space 205 after the substrate processing, it is considered that the heat of the dielectric plate 512b is lowered more easily than that of the dielectric plate 512a. The same also applies to the dielectric plate 512c. Therefore, in the present step, the dielectric plates 512 may be heated independently depending on the conditions of the dielectric plates 512.

When the temperature of each of the dielectric plates 512 is heated independently, a supply time of supplying the microwave in each of the electromagnetic wave suppliers 510 is adjusted. For example, when the temperature of the dielectric plate 512b is lower than that of the dielectric plate 512a, a heating time for the dielectric plate 512b is set to be longer than that of the dielectric plate 512a. Alternatively, a radiation amount of the microwave supplied to each of the dielectric plates 512 may be adjusted by opening and closing the shutter 519.

In a manner described above, it is possible to uniformize the film quality between the lots (more specifically, between the substrates S).

### Other Embodiments of the Present Disclosure

The technique of the present disclosure is described in detail by way of the embodiments mentioned above. However, the technique of the present disclosure is not limited thereto, and may be modified in various ways without departing from the scope thereof.

For example, the embodiments mentioned above are described by way of an example in which, in the film forming process performed by the substrate processing apparatus, the silicon nitride film is formed on the substrate S by using the DCS gas as the first gas and the NH₃ gas as the second gas and alternately supplying the DCS gas and the NH₃ gas. However, the technique of the present disclosure is not limited thereto. That is, the process gases used in the film forming process are not limited to the DCS gas and the NH₃ gas, and other gases may be used to form different type of films. In addition, the technique of the present disclosure may also be applied to film forming processes using three or more different process gases as long as the three or more different process gases are non-simultaneously supplied (that is, supplied in a non-overlapping manner) to form various films. Specifically, for example, instead of silicon, an element such as titanium (Ti), zirconium (Zr) and hafnium (Hf) may be used as the first element. In addition, for example, instead of nitrogen, an element such as argon (Ar) may be used as the second element.

For example, the temperature adjusting step may be performed as follows. As an example, the heater 213 in the process chamber 201 may be operated in a state where the inert gas is filled in the process space 205 between the dielectric plate 252 and the heater 213. Thereby, since the heat generated by the heater 213 is circulated, it is possible to uniformly heat the dielectric plate 252.

For example, the embodiments mentioned above are described by way of an example in which the film forming process is performed by the substrate processing apparatus. However, the technique of the present disclosure is not limited thereto. That is, the technique of the present disclosure may be applied not only to the film forming process of forming the film exemplified in the embodiments mentioned above but also to other film forming processes of forming other films. For example, the specific contents of the film forming process are not limited to those exemplified in the embodiments mentioned above. For example, in addition to or instead of the film forming process mentioned above, the technique of the present disclosure may be applied to a process such as an annealing process, a diffusion process, an oxidation process, a nitridation process and a lithography process. In addition, the technique of the present disclosure may also be applied to other substrate processing apparatuses such as an annealing apparatus, an etching apparatus, an oxidation apparatus, a nitridation apparatus, an exposure apparatus, a coating apparatus, a drying apparatus, a heating apparatus, an apparatus using the plasma, and a combination thereof. The technique of the present disclosure may also be applied when a constituent of one of the embodiments mentioned above is substituted with another constituent of another embodiment, or when a constituent of one of the embodiments mentioned above is added to another embodiment. In addition, the technique of the present disclosure may also be applied when the constituent of the embodiments mentioned above is omitted or substituted, or when a constituent is added to the embodiments mentioned above.

For example, it is preferable that recipes used in processes are prepared individually in accordance with contents of the processes and stored in the memory 403 via an electric communication line or the external memory 282. When starting each process, it is preferable that the CPU 401 selects an appropriate recipe among the recipes stored in the memory 403 in accordance with the contents of each process. Thus, various films of different composition ratios, qualities and thicknesses can be formed in a reliably reproducible manner by using a single substrate processing apparatus. In addition, since a burden on an operating personnel can be reduced, various processes can be performed quickly while avoiding an error in operating the substrate processing apparatus.

The recipe described above is not limited to creating a new recipe. For example, the recipe may be prepared by changing an existing recipe stored (or installed) in the substrate processing apparatus in advance. When changing the existing recipe to a new recipe, the new recipe may be installed in the substrate processing apparatus via the electric communication line or a recording medium in which the new recipe is stored. Further, the existing recipe already stored in the substrate processing apparatus may be directly changed to the new recipe by operating the input/output device 281 of the substrate processing apparatus.

For example, the embodiments mentioned above are described by way of an example in which a single wafer type substrate processing apparatus capable of simultaneously processing one or several substrates is used to form the film. However, the technique of the present disclosure is not limited thereto. For example, the technique of the present disclosure may be preferably applied when a batch type substrate processing apparatus capable of simultaneously processing a plurality of substrates is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

Process procedures and process conditions of each process using the substrate processing apparatuses exemplified above may be substantially the same as those of the embodiments or modified examples mentioned above. Even in such a case, it is possible to obtain substantially the same effects as in the embodiments or the modified examples mentioned above.

In addition, the embodiments and the modified examples mentioned above may be appropriately combined. The process procedures and the process conditions of each combination thereof may be substantially the same as those of the embodiments mentioned above or the modified examples mentioned above.

According to some embodiments of the present disclosure, it is possible to process the plurality of substrates such that the film quality is uniformized even when the processing environment between the plurality of substrates varies.

What is claimed is:

1. A substrate processing apparatus comprising:
a process chamber in which a substrate is processed;
a dielectric structure provided in the process chamber;
an electromagnetic wave supplier configured to supply an electromagnetic wave to the dielectric structure;
a heating medium supplier capable of supplying a heating medium to the dielectric structure; and
a controller configured to be capable of controlling the heating medium supplier such that the heating medium is supplied to the dielectric structure when a temperature of the dielectric structure is equal to or lower than a predetermined temperature before processing the substrate.

2. The substrate processing apparatus of claim 1, further comprising
a temperature meter capable of measuring the temperature of the dielectric structure.

3. The substrate processing apparatus of claim 1, wherein a plasma of the heating medium is generated in the process chamber in a state where the heating medium is supplied from the heating medium supplier to the dielectric structure.

4. The substrate processing apparatus of claim 3, further comprising
a substrate support provided in the process chamber and provided with a plurality of support surfaces capable of supporting the substrate,
wherein the substrate support is further configured such that a support surface among the plurality of support surfaces is not maintained directly below the dielectric structure while the plasma is generated.

5. The substrate processing apparatus of claim 3, further comprising
a substrate support provided in the process chamber and provided with a plurality of support surfaces capable of supporting the substrate,
wherein a support surface among the plurality of support surfaces and the dielectric structure are moved relative to each other in at least a part of a period during which the plasma is generated.

6. The substrate processing apparatus of claim 3, further comprising
a substrate support provided in the process chamber and provided with a plurality of support surfaces capable of supporting the substrate,
wherein the substrate support is capable of being rotated and configured to rotate the plurality of support surfaces in at least a part of a period during which the plasma is generated.

7. The substrate processing apparatus of claim 1, further comprising
a heater configured to be capable of heating the heating medium while a space between the heater and the dielectric structure is filled with the heating medium.

8. The substrate processing apparatus of claim 1, further comprising
one or more dielectric structures,
wherein the controller is further configured to be capable of controlling the heating medium supplier so as to respectively adjust a temperature of each of the dielectric structure and the one or more dielectric structures.

9. The substrate processing apparatus of claim 8, wherein the controller is further configured to be capable of controlling a transfer robot so as to load a subsequent substrate after each of the dielectric structure and the one or more dielectric structures reaches a target temperature.

10. The substrate processing apparatus of claim 1, further comprising
one or more dielectric structures,
wherein the controller is further configured to be capable of controlling the electromagnetic wave supplier so as to respectively control an amount of the electromagnetic wave radiated to each of the dielectric structure and the one or more dielectric structures.

11. The substrate processing apparatus of claim 1, further comprising
a waveguide corresponding to the dielectric structure,
wherein the waveguide is provided with a shutter capable of restricting a movement of the electromagnetic wave.

12. The substrate processing apparatus of claim 1, further comprising
one or more dielectric structures,
wherein the heating medium supplier is capable of supplying the heating medium to each of the dielectric structure and the one or more dielectric structures.

13. The substrate processing apparatus of claim 1, further comprising
a substrate support provided in the process chamber and provided with a plurality of support surfaces capable of supporting the substrate,
wherein the dielectric structure comprises:
a first dielectric structure located at a position facing the substrate supported on the substrate support and facing a center of the substrate; and
a second dielectric structure arranged in a circumferential direction around the first dielectric structure, and
wherein the controller is further configured to be capable of controlling the heating medium supplier so as to independently increase a temperature of the first dielectric structure and a temperature of the second dielectric structure.

14. The substrate processing apparatus of claim 13, further comprising
an exhauster configured to exhaust an inner atmosphere of the process chamber through an outer periphery of the substrate support,
wherein the controller is further configured to be capable of controlling the heating medium supplier such that a heating time for the second dielectric structure is set to be longer than that of the first dielectric structure.

15. The substrate processing apparatus of claim 13, wherein the dielectric structure further comprises one or more second dielectric structures, and
wherein the second dielectric structure and the one or more second dielectric structures are arranged in the circumferential direction around the first dielectric structure.

16. The substrate processing apparatus of claim 2, further comprising:
one or more dielectric structures; and
one or more temperature meters,
wherein the temperature meter and the one or more temperature meters are provided at the dielectric structure and the one or more dielectric structures, respectively.

17. The substrate processing apparatus of claim 1, further comprising
one or more dielectric structures,
wherein the controller is further configured to be capable of controlling a transfer robot such that a subsequent substrate to be processed is loaded into the process chamber after a temperature difference among the dielectric structure and the one or more dielectric structures is within a predetermined range.

18. A substrate processing method comprising:
(a) supplying a heating medium to a dielectric structure when a temperature of the dielectric structure is equal to or lower than a predetermined temperature before processing a substrate; and
(b) processing the substrate by supplying an electromagnetic wave to the dielectric structure and supplying a process gas to a process chamber while the substrate is accommodated in the process chamber.

19. A method of manufacturing a semiconductor device, comprising
the method of claim 18.

20. A non-transitory computer-readable recording medium storing a program that causes, by a computer, a substrate processing apparatus to perform:
(a) supplying a heating medium to a dielectric structure when a temperature of the dielectric structure is equal to or lower than a predetermined temperature before processing a substrate; and
(b) processing the substrate by supplying an electromagnetic wave to the dielectric structure and supplying a process gas to a process chamber while the substrate is accommodated in the process chamber.
